(19) United States
(12) Patent Application Publication
(10) Pub. No.: US 2024/0160812 A1
(43) Pub. Date: May 16, 2024

(54) TRAJECTORY IMPUTATION AND PREDICTION

(71) Applicant: Honda Motor Co., Ltd., Tokyo (JP)

(72) Inventors: Yi XU, San Jose, CA (US); Armin BAZARJANI, Los Angeles, CA (US); Hyung-gun CHI, West Lafayette, IN (US); Chiho CHOI, San Jose, CA (US)

(21) Appl. No.: 18/182,195

(22) Filed: Mar. 10, 2023

Related U.S. Application Data
(60) Provisional application No. 63/424,449, filed on Nov. 10, 2022.

(51) Int. Cl. G06F 30/27

(52) U.S. Cl. CPC G06F 30/27

(57) ABSTRACT

Systems and methods for trajectory imputation and prediction are provided. In one embodiment, a method includes generating a spatial missing pattern in an imputation stream by applying a binary mask to an observational dataset over a number of past timesteps. The method includes extracting spatial features from the spatial missing pattern for the number of past time steps. The method includes encoding the spatial features of the observational dataset into imputation latent variables in a latent space based on the spatial missing pattern. The method includes generating a temporal missing pattern by modeling temporal dependency as temporal decay from the past time to the first time based on the latent space. The method includes determining imputation trajectories based on the imputation latent variables and the temporal missing pattern. The method includes predicting future trajectories for the number of agents for a number of future timesteps based temporal missing pattern.

### BACKGROUND

Modeling and predicting future trajectories plays an indispensable role in many applications such as autonomous driving, path planning, motion capture, behavior understanding, etc. In such applications, the goal of the trajectory prediction is to output the future locations of target agents conditioned on their historic movements. This is a challenging modeling task as movement patterns are both complex and subtle to quantify. Existing methods usually assume the observations of agents are totally complete, a conjecture that is too strong to satisfy.

### BRIEF DESCRIPTION

According to one aspect, a system for trajectory imputation and prediction is provided. The system includes a memory storing instructions that when executed by a processor cause the processor to perform a method for trajectory imputation and prediction. The instructions cause the processor to generate a spatial missing pattern in an imputation stream by applying a binary mask to an observational dataset representing past actions for a number of agents over a number of past timesteps from a past time to a first time. The instructions also cause the processor to extract one or more spatial features from the spatial missing pattern for the number of past time steps. The instructions cause the processor to encode the one or more spatial features of the observational dataset into imputation latent variables in a latent space based on the spatial missing pattern. The instructions cause the processor to generate a temporal missing pattern by modeling temporal dependency as temporal decay from the past time to the first time based on the latent space. The instructions cause the processor to determine imputation trajectories based on the imputation latent variables and the temporal missing pattern. The instructions cause the processor to predict future trajectories for the number of agents for a number of future timesteps from second time, after the first time, to a future time based temporal missing pattern.

According to one aspect, a computer-implemented method for trajectory imputation and prediction is provided. The computer-implemented method includes generating a spatial missing pattern in an imputation stream by applying a binary mask to an observational dataset representing past actions for a number of agents over a number of past timesteps from a past time to a first time. The computer-implemented method includes extracting one or more spatial features from the spatial missing pattern for the number of past time steps. The computer-implemented method includes encoding the one or more spatial features of the observational dataset into imputation latent variables in a latent space based on the spatial missing pattern. The computer-implemented method includes generating a temporal missing pattern by modeling temporal dependency as temporal decay from the past time to the first time based on the latent space. The computer-implemented method includes determining imputation trajectories based on the imputation latent variables and the temporal missing pattern. The computer-implemented method includes predicting future trajectories for the number of agents for a number of future timesteps from second time, after the first time, to a future time based temporal missing pattern.

According to yet another aspect, a non-transitory computer readable storage medium storing instructions that when executed by a computer, which includes a processor, perform a method for trajectory imputation and prediction. The method includes generating a spatial missing pattern in an imputation stream by applying a binary mask to an observational dataset representing past actions for a number of agents over a number of past timesteps from a past time to a first time. The method includes extracting one or more spatial features from the spatial missing pattern for the number of past time steps. The method includes encoding the one or more spatial features of the observational dataset into imputation latent variables in a latent space based on the spatial missing pattern. The method includes generating a temporal missing pattern by modeling temporal dependency as temporal decay from the past time to the first time based on the latent space. The method includes determining imputation trajectories based on the imputation latent variables and the temporal missing pattern. The method includes predicting future trajectories for the number of agents for a number of future timesteps from second time, after the first time, to a future time based temporal missing pattern.

### BRIEF DESCRIPTION OF THE DRAWINGS

FIG. 1 is an exemplary component diagram of a system for trajectory imputation and prediction, according to one aspect.

FIG. 2A is an exemplary agent environment, at a first past time, of a system for trajectory imputation and prediction, according to one aspect.

FIG. 2B is an exemplary agent environment, at a second past time, of a system for trajectory imputation and prediction, according to one aspect.

FIG. 2C is an exemplary agent environment, at a third past time, of a system for trajectory imputation and prediction, according to one aspect.

FIG. 3 is an exemplary process flow of a method trajectory imputation and prediction, according to one aspect.

FIG. 4 is exemplary network architecture for trajectory imputation and prediction, according to one aspect.

FIG. 5 is an exemplary timing diagram for trajectory imputation and prediction, according to one aspect.

FIG. 6 is an illustration of an example computer-readable medium or computer-readable device including processor-executable instructions configured to embody one or more of the provisions set forth herein, according to one aspect.

### DETAILED DESCRIPTION

In a multi-agent scenario, observational data may not be available for each of the agents moving through agent environment resulting in an imputation stream. The imputation stream includes some but is missing values for one or more agent observations. The systems and methods described herein impute missing values of all agent observations from time step t₁ to tₚ and meanwhile predict their future trajectory from time step tₚ₊₁ to t_{f} conditioned on their incomplete observations.

Jointly learning the imputation and prediction promotes the two-way transfer of valuable information, thus the two tasks may mutually support each other. Here, a Graph-based Conditional Variational Recurrent Neural Network (GC-VRNN) is provided to jointly handle these two tasks, including two streams: an imputation stream and a prediction stream. In both streams, a Multi-Space Graph Neural Network (MS-GNN) may encode agent-wise spatial features of incomplete trajectories from different representation spaces into latent variables. The spatial missing pattern is specifically emphasized during this process. Afterwards, a Conditional VRNN is adopted to model temporal dependencies across subsequent time steps. Meanwhile, a temporal decay (TD) module is included to leverage temporal missing pattern recurrently. The method also allows valuable information to be transferred between the two tasks through the latent space, this is also further encouraged via a Kullback-Leibler (KL) divergence loss to help bridge the two streams together.

### DEFINITIONS

The following includes definitions of selected terms employed herein. The definitions include various examples and/or forms of components that fall within the scope of a term and that may be used for implementation. The examples are not intended to be limiting. Furthermore, the components discussed herein, may be combined, omitted, or organized with other components or into different architectures.

“Agent” as used herein are machines that move through or manipulate an environment. Exemplary agents may include, but is not limited to, robots, vehicles, or other self-propelled machines. The agent may be autonomously, semi-autonomously, or manually operated.

“Agent system,” as used herein may include, but is not limited to, any automatic or manual systems that may be used to enhance the agent, propulsion, and/or operation. Exemplary systems include, but are not limited to: an electronic stability control system, an anti-lock brake system, a brake assist system, an automatic brake prefill system, a low speed follow system, a cruise control system, a collision warning system, a collision mitigation braking system, an auto cruise control system, a lane departure warning system, a blind spot indicator system, a lane keep assist system, a navigation system, a steering system, a transmission system, brake pedal systems, an electronic power steering system, visual devices (e.g., camera systems, proximity sensor systems), an electronic pretensioning system, a monitoring system, a passenger detection system, a suspension system, a seat configuration system, a cabin lighting system, an audio system, a sensory system, an interior or exterior camera system among others.

“Bus,” as used herein, refers to an interconnected architecture that is operably connected to other computer components inside a computer or between computers. The bus may transfer data between the computer components. The bus may be a memory bus, a memory processor, a peripheral bus, an external bus, a crossbar switch, and/or a local bus, among others. The bus may also be a bus that interconnects components inside an agent using protocols such as Media Oriented Systems Transport (MOST), Controller Area network (CAN), Local Interconnect network (LIN), among others.

“Component,” as used herein, refers to a computer-related entity (e.g., hardware, firmware, instructions in execution, combinations thereof). Computer components may include, for example, a process running on a processor, a processor, an object, an executable, a thread of execution, and a computer. A computer component(s) may reside within a process and/or thread. A computer component may be localized on one computer and/or may be distributed between multiple computers.

“Computer communication,” as used herein, refers to a communication between two or more communicating devices (e.g., computer, personal digital assistant, cellular telephone, network device, vehicle, computing device, infrastructure device, roadside equipment) and may be, for example, a network transfer, a data transfer, a file transfer, an applet transfer, an email, a hypertext transfer protocol (HTTP) transfer, and so on. A computer communication may occur across any type of wired or wireless system and/or network having any type of configuration, for example, a local area network (LAN), a personal area network (PAN), a wireless personal area network (WPAN), a wireless network (WAN), a wide area network (WAN), a metropolitan area network (MAN), a virtual private network (VPN), a cellular network, a token ring network, a point-to-point network, an ad hoc network, a mobile ad hoc network, a vehicular ad hoc network (VANET), a vehicle-to-vehicle (V2V) network, a vehicle-to-everything (V2X) network, a vehicle-to-infrastructure (V2I) network, among others. Computer communication may utilize any type of wired, wireless, or network communication protocol including, but not limited to, Ethernet (e.g., IEEE 802.3), WiFi (e.g., IEEE 802.11), communications access for land mobiles (CALM), WiMax, Bluetooth, Zigbee, ultra-wideband (UWAB), multiple-input and multiple-output (MIMO), telecommunications and/or cellular network communication (e.g., SMS, MMS, 3G, 4G, LTE, 5G, GSM, CDMA, WAVE), satellite, dedicated short range communication (DSRC), among others.

“Communication interface” as used herein may include input and/or output devices for receiving input and/or devices for outputting data. The input and/or output may be for controlling different agent features, which include various agent components, systems, and subsystems. Specifically, the term “input device” includes, but is not limited to: keyboard, microphones, pointing and selection devices, cameras, imaging devices, video cards, displays, push buttons, rotary knobs, and the like. The term “input device” additionally includes graphical input controls that take place within a user interface which may be displayed by various types of mechanisms such as software and hardware-based controls, interfaces, touch screens, touch pads or plug and play devices. An “output device” includes, but is not limited to, display devices, and other devices for outputting information and functions.

“Computer-readable medium,” as used herein, refers to a non-transitory medium that stores instructions and/or data. A computer-readable medium may take forms, including, but not limited to, non-volatile media, and volatile media. Non-volatile media may include, for example, optical disks, magnetic disks, and so on. Volatile media may include, for example, semiconductor memories, dynamic memory, and so on. Common forms of a computer-readable medium may include, but are not limited to, a floppy disk, a flexible disk, a hard disk, a magnetic tape, other magnetic medium, an ASIC, a CD, other optical medium, a RAM, a ROM, a memory chip or card, a memory stick, and other media from which a computer, a processor or other electronic device may read.

“Database,” as used herein, is used to refer to a table. In other examples, “database” may be used to refer to a set of tables. In still other examples, “database” may refer to a set of data stores and methods for accessing and/or manipulating those data stores. In one embodiment, a database may be stored, for example, at a disk, data store, and/or a memory. A database may be stored locally or remotely and accessed via a network.

“Data store,” as used herein may be, for example, a magnetic disk drive, a solid-state disk drive, a floppy disk drive, a tape drive, a Zip drive, a flash memory card, and/or a memory stick. Furthermore, the disk may be a CD-ROM (compact disk ROM), a CD recordable drive (CD-R drive), a CD rewritable drive (CD-RW drive), and/or a digital video ROM drive (DVD ROM). The disk may store an operating system that controls or allocates resources of a computing device.

“ D ispl ay,” as used herein may include, but is not limited to, LED display panels, LCD display panels, CRT display, touch screen displays, among others, that often display information. The display may receive input (e.g., touch input, keyboard input, input from various other input devices, etc.) from a user. The display may be accessible through various devices, for example, though a remote system. The display may also be physically located on a portable device, mobility device, or host.

“Logic circuitry,” as used herein, includes, but is not limited to, hardware, firmware, a non-transitory computer readable medium that stores instructions, instructions in execution on a machine, and/or to cause (e.g., execute) an action(s) from another logic circuitry, module, method and/or system. Logic circuitry may include and/or be a part of a processor controlled by an algorithm, a discrete logic (e.g., ASIC), an analog circuit, a digital circuit, a programmed logic device, a memory device containing instructions, and so on. Logic may include one or more gates, combinations of gates, or other circuit components. Where multiple logics are described, it may be possible to incorporate the multiple logics into one physical logic. Similarly, where a single logic is described, it may be possible to distribute that single logic between multiple physical logics.

“Memory,” as used herein may include volatile memory and/or nonvolatile memory. Non-volatile memory may include, for example, ROM (read only memory), PROM (programmable read only memory), EPROM (erasable PROM), and EEPROM (electrically erasable PROM). Volatile memory may include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory may store an operating system that controls or allocates resources of a computing device.

“Module,” as used herein, includes, but is not limited to, non-transitory computer readable medium that stores instructions, instructions in execution on a machine, hardware, firmware, software in execution on a machine, and/or combinations of each to perform a function(s) or an action(s), and/or to cause a function or action from another module, method, and/or system. A module may also include logic, a software-controlled microprocessor, a discrete logic circuit, an analog circuit, a digital circuit, a programmed logic device, a memory device containing executing instructions, logic gates, a combination of gates, and/or other circuit components. Multiple modules may be combined into one module and single modules may be distributed among multiple modules.

“Operable connection,” or a connection by which entities are “operably connected,” is one in which signals, physical communications, and/or logical communications may be sent and/or received. An operable connection may include a wireless interface, firmware interface, a physical interface, a data interface, and/or an electrical interface.

“Portable device,” as used herein, is a computing device typically having a display screen with user input (e.g., touch, keyboard) and a processor for computing. Portable devices include, but are not limited to, handheld devices, mobile devices, smart phones, laptops, tablets, e-readers, smart speakers. In some embodiments, a “portable device” could refer to a remote device that includes a processor for computing and/or a communication interface for receiving and transmitting data remotely.

“Processor,” as used herein, processes signals and performs general computing and arithmetic functions. Signals processed by the processor may include digital signals, data signals, computer instructions, processor instructions, messages, a bit, a bit stream, that may be received, transmitted and/or detected. Generally, the processor may be a variety of various processors including multiple single and multicore processors and co-processors and other multiple single and multicore processor and co-processor architectures. The processor may include logic circuitry to execute actions and/or algorithms.

“Vehicle,” as used herein, refers to any moving vehicle that is capable of carrying one or more users and is powered by any form of energy. The term “vehicle” includes, but is not limited to cars, trucks, vans, minivans, SUVs, motorcycles, scooters, boats, go-karts, amusement ride cars, rail transport, personal watercraft, and aircraft. Further, the term “vehicle” may refer to an electric vehicle (EV) that is powered entirely or partially by one or more electric motors powered by an electric battery. The EV may include battery electric vehicles and plug-in hybrid electric vehicles (PHEV). The term “vehicle” may also refer to an autonomous vehicle and/or self-driving vehicle powered by any form of energy.

A “vehicle system,” as used herein may include, but is not limited to, any automatic or manual systems that may be used to enhance the vehicle, driving, and/or operation. Exemplary vehicle systems include, but are not limited to: an electronic stability control system, an anti-lock brake system, a brake assist system, an automatic brake prefill system, a low speed follow system, a cruise control system, an auto cruise control system, a lane departure warning system, a blind spot indicator system, a lane keep assist system, a navigation system, a transmission system, brake pedal systems, an electronic power steering system, visual devices (e.g., camera systems, proximity sensor systems), a climate control system, an electronic pretensioning system, a monitoring system, a passenger detection system, a vehicle suspension system, a vehicle seat configuration system, a vehicle cabin lighting system, an audio system, a sensory system, among others.

### I. SYSTEM OVERVIEW

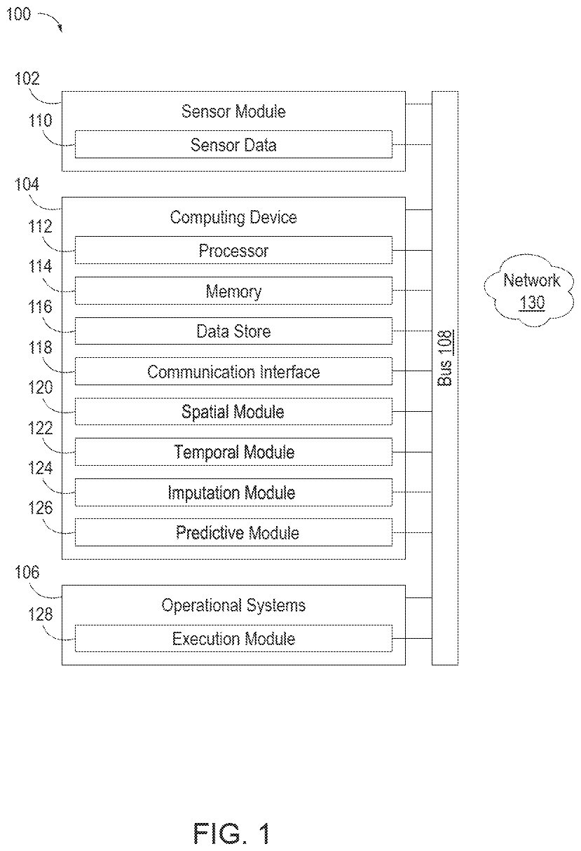

Referring now to the drawings, the drawings are for purposes of illustrating one or more exemplary embodiments and not for purposes of limiting the same. FIG. 1 is an exemplary component diagram of an operating environment 100 trajectory imputation and prediction, according to one aspect. The operating environment 100 includes a sensor module 102, a computing device 104, and operational systems 106 interconnected by a bus 108. The components of the operating environment 100, as well as the components of other systems, hardware architectures, and software architectures discussed herein, may be combined, omitted, or organized into different architectures for various embodiments. The computing device 104 may be implemented with a device or remotely stored. For example, the components and functions of the computing device 104 may be implemented with other devices, such as a portable device (not shown) or another device connected via a network (e.g., a network 130).

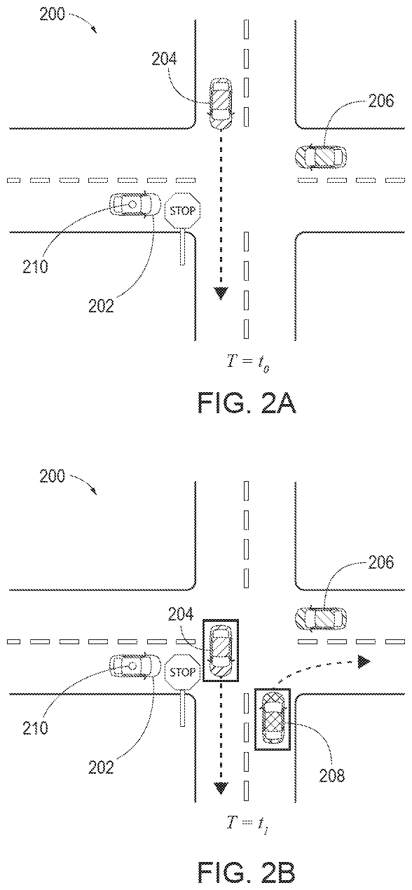

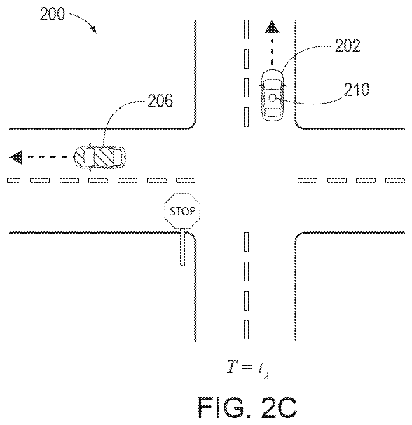

The computing device 104 may be implemented as a part of an ego agent, such as the first agent 202 of the roadway 200, shown in FIG. 2. The ego agent may be a bipedal, two-wheeled or four-wheeled robot, a vehicle, or a self-propelled machine. For example, in another embodiment, the ego agent may be configured as a humanoid robot. The ego agent may take the form of all or a portion of a robot. In a vehicular embodiment, the computing device 104 may be implemented as part of a telematics unit, a head unit, a navigation unit, an infotainment unit, an electronic control unit, among others of the ego agent. For clarity, the ego agent in embodiments described herein will be referred to as the first agent 202. However, one or more agents may be an ego agent. For example, in the vehicular embodiment, the second agent 204, the third agent 206, and/or the fourth agent 208 of the roadway 200 may act as an ego agent.

The computing device 104 may be capable of providing wired or wireless computer communications utilizing various protocols to send and/or receive electronic signals internally to/from components of the operating environment 100. Additionally, the computing device 104 may be operably connected for internal computer communication via the bus 108 (e.g., a Controller Area Network (CAN) or a Local Interconnect Network (LIN) protocol bus) to facilitate data input and output between the computing device 104 and the components of the operating environment 100, such as the sensor module 102 and/or the operational systems 106.

The first agent 202 may include sensors for sensing objects and the roadway 200. For example, the first agent 202 may include an image sensor 210. The image sensor 210 may be a light sensor to capture light data from around the first agent 202. For example, a light sensor may rotate 360 degrees around first agent 202 and collect the sensor data 110 in sweeps. Conversely, an image sensor 210 may be omnidirectional and collect sensor data 110 from all directions simultaneously. The image sensor 210 of an agent may emit one or more laser beams of ultraviolet, visible, or near infrared light toward the surrounding environment of the first agent 202. In some embodiments, the image sensor 210 may be a monocular camera.

The image sensor 210 may positioned on the first agent 202. For example, suppose that the first agent 202 is a vehicle. One or more sensors may be positioned at external front and/or side portions of the first agent 202, including, but not limited to different portions of the vehicle bumper, vehicle front lighting units, vehicle fenders, and the windshield. Additionally, the sensors may be disposed at internal portions of the first agent 202 including, in the vehicular embodiment, the vehicle dashboard (e.g., dash mounted camera), rear side of a vehicle rear view mirror, etc. Sensors may be positioned on a planar sweep pedestal (not shown) that allows the image sensor 210 to be rotated to capture images of the environment at various angles.

The image sensor 210 is associated with intrinsic parameters. The intrinsic parameters link the pixel coordinates of an image with corresponding coordinates in the camera reference frame. The intrinsic parameters identify the transformation between the camera reference frame and the world reference frame. For example, the intrinsic parameters may include the position, angle, field of view (FOV), location, etc. of the image sensor 210, the size of pixels in the image, and the orientation of the image sensor 210, among others.

Accordingly, the sensors, such as the image sensor 210, and/or the sensor module 102 are operable to sense a measurement of data associated with the first agent 202, the operating environment 100, the roadway 200, and/or the operational systems 106 and generate a data signal indicating said measurement of data. These data signals may be converted into other data formats (e.g., numerical) and/or used by the sensor module 102, the computing device 104, and/or the operational systems 106 to generate sensor data 110 including data metrics and parameters. The sensor data 110 may be received by the sensor module as an input image. Based on the location of the image sensor 210, the input image may be a perspective space image defined relative to the position and viewing direction of the first agent 202.

The computing device 104 includes a processor 112, a memory 114, a data store 116, and a communication interface 118, which are each operably connected for computer communication via a bus 108 and/or other wired and wireless technologies. The communication interface 118 provides software and hardware to facilitate data input and output between the components of the computing device 104 and other components, networks, and data sources, which will be described herein. Additionally, the computing device 104 also includes a spatial module 120, a temporal module 122, a imputation module 124, and a predictive module 126 facilitated by the components of the operating environment 100.

The spatial module 120, the temporal module 122, the imputation module 124, and the predictive module 126 may be artificial neural networks that act as a framework for machine learning, including deep reinforcement learning. For example, the spatial module 120, the temporal module 122, the imputation module 124, and the predictive module 126 may be a convolution neural network (CNN). In one embodiment, the spatial module 120, the temporal module 122, the imputation module 124, and the predictive module 126 may include a conditional generative adversarial network (cGAN), multi-space graph neural network (MS-GNN) and/or a graph-based conditional variational recurrent neural network (GC-VRNN).

One or more of spatial module 120, the temporal module 122, the imputation module 124, and the predictive module 126 may be a graphical representation neural network that is applied to graphical representation structures. In another embodiment, the spatial module 120, the temporal module 122, the imputation module 124, and the predictive module 126 may include an input layer, an output layer, and one or more hidden layers, which may be convolutional filters. In some embodiments, one or more of the modules may include Long Short Term Memory (LSTM) networks and LSTM variants (e.g., E-LSTM, G-LSTM, etc.).

The computing device 104 is also operably connected for computer communication (e.g., via the bus 108 and/or the communication interface 118) to one or more operational systems 106. The operational systems 106 may include, but are not limited to, any automatic or manual systems that may be used to enhance the first agent 202, operation, and/or propulsion such as agent systems or vehicle systems. The operational systems 106 include an execution module 128. The execution module 128 monitors, analyses, and/or operates the first agent 202, to some degree. For example, the execution module 128 may store, calculate, and provide directional information and facilitate features like vectoring and obstacle avoidance among others. In the vehicular embodiment, the execution module 128 may provide operational data to vehicle systems, such as the steering system, that cause the first agent 202 to operate autonomously. In some embodiments, the execution module 128 may be a Proportional, Integral, Derivative (PID) controller. Continuing the vehicular embodiment described above, the execution module 128 may be a longitudinal PID controller. The operational systems 106 may be dependent on the implementation.

The operational systems 106 also include and/or are operably connected for computer communication to the sensor module 102. For example, one or more sensors of the sensor module 102, such as the image sensor 210, may be incorporated with execution module 128 to monitor characteristics of the environment of the first agent 202 or the first agent 202 itself. For example, in the vehicular embodiment, the image sensor 210 may be incorporated with execution module 128 to monitor characteristics of the roadway 200. Suppose that the execution module 128 is facilitating execution of a right turn onto a street. The execution module 128 may receive sensor data 110 from the sensor module 102 to confirm that vehicles present on the street are yielding as expected.

The sensor module 102, the computing device 104, and/or the operational systems 106 are also operatively connected for computer communication to the network 130. The network 130 is, for example, a data network, the Internet, a wide area network (WAN) or a local area (LAN) network. The network 130 serves as a communication medium to various remote devices (e.g., databases, web servers, remote servers, application servers, intermediary servers, client machines, other portable devices). Detailed embodiments describing exemplary methods using the system and network configuration discussed above will now be discussed in detail.

### II. METHODS

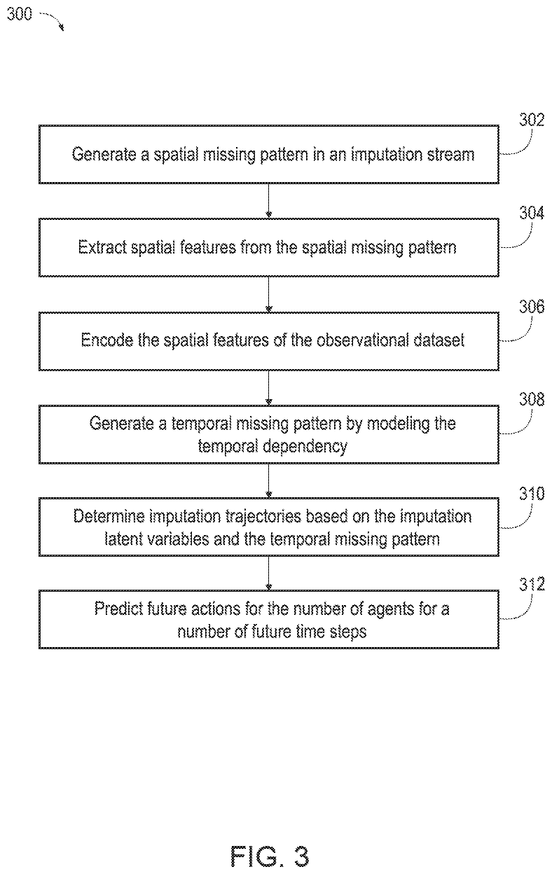

Referring now to FIG. 3, a method 300 for trajectory imputation and prediction will now be described according to an exemplary embodiment. FIG. 3 will also be described with reference to FIGS. 1, 2A, 2B, 2C, 4, 5, and 6. For simplicity, the method 300 will be described as a sequence of elements, but it is understood that the elements of the method 300 may be organized into different architectures, blocks, stages, and/or processes.

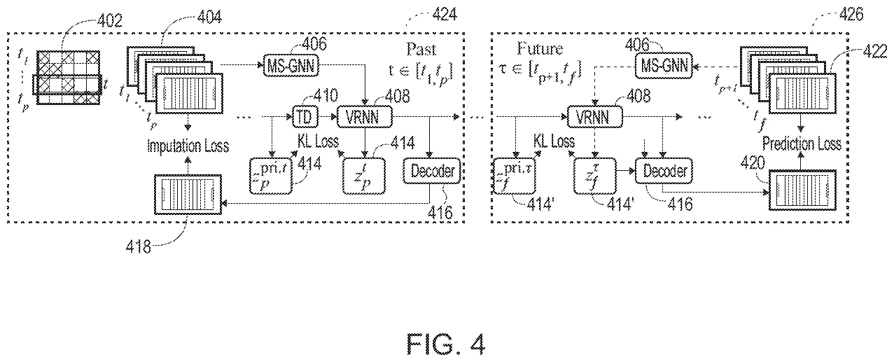

At block 302 the method 300 includes the spatial module 120 generating a spatial missing pattern in an imputation stream by applying a binary mask 402 to an observational dataset 404, shown in FIG. 4. The observational dataset 404 is sensor data 110 that is missing data about one or more agents. The observational dataset 404 may include sensor data 110 for a number of agents over a number of past timesteps from a past time to a current time. The imputation stream includes an observational dataset, Ω, 404 of N agents as Ω={1, 2, . . . , N} over the time step t₁ to tₚ, where X^{≤t}^{ₚ}={xᵢ¹, . . . , xᵢ^{t}, . . . , xᵢ^{t}^{ₚ}} denotes the observed trajectory of an agent i ∈Ω, where xᵢ^{t} ∈ [symbol] ² denotes the 2D coordinates of the agent i at time step t ∈ [t₁, tₚ]. Then the observed trajectory set may be defined as X_{Ω}^{≤t}^{ₚ}={Xᵢ^{≤t}^{ₚ}|∀i ∈ Ω}. In this manner, the observational dataset 404 may represent past actions for the number of agents over a number of past timesteps from a past time to a first time.

The observational dataset 404 may be missing some historical data for one or more of the agents at past time steps due to occlusion, sensor failure, etc. For example, turning to FIG. 2A, a first agent 202, a second agent 204, and a third agent 206 are traveling in an roadway 200, that includes an intersection, at a first past time, to. The first agent 202 is stopped at the intersection. The second agent 204 is moving through the intersection in a straight line. The third agent 206 is approaching the intersection. In FIG. 2B, at a second past time , ti, the second agent 204 is proceeding through the intersection. If the first agent 202, is the host agent, then the second agent 204 may occlude the third agent 206. Additionally, at second past time , t₁, a fourth agent 208 as reached the intersection and is turning right. Moving to FIG. 2C, at a third past time, t₂, the second agent 204 and the fourth agent 208 are no longer visible to the first agent 202. The first agent 202 has proceeded to make a left turn and the third agent 206 has proceeded through the intersection in the roadway 200.

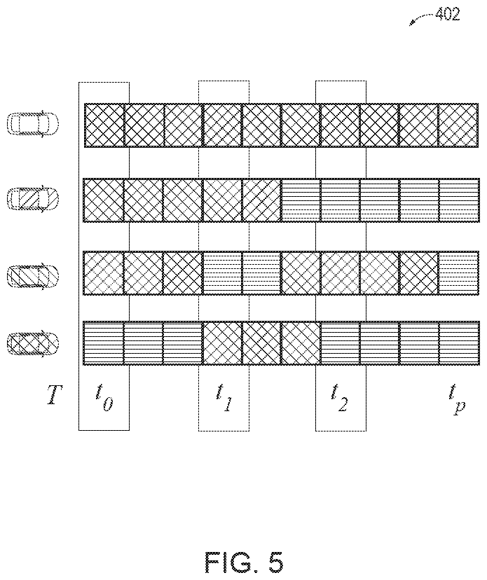

The binary mask 402 represents the missing locations with a masking matrix given by Mᵢ^{≤t}^{ₚ}={mᵢ¹, . . . , mᵢ^{t}, . . . , mᵢ^{t}^{ₚ}} valued in {0,1}, where mᵢ^{t}=1 whenever observation is available at time step t and 0 otherwise. In some embodiments, the state of one agent is either fully observable or fully unobservable at a given time step. For example, the binary mask 402 corresponding to the roadway 200 in FIG. 2A-2C is shown relative to the timing diagram of FIG. 5 in which striped squares represent a lack of observational data in the observational dataset 404 for an agent at a timestep and hashes represent the presence of observational data in the dataset. Because there is no sensor data for the fourth agent 208 at the first past time, to, the blocks corresponding to the fourth agent 208 at the first past time, to, is striped. However, sensor data 110 for the first agent 202, the second agent 204, and the third agent 206 is present.

If the first agent 202 is the host agent, then the blocks corresponding to the third agent 206 at the second past time, t₁, is striped. However, there is sensor data 110 in the observational dataset 404 regarding the first agent 202, the second agent 204, and the fourth agent 208. At the third past time, t₂, there is no sensor data 110 in the observational dataset 404 regarding the second agent 204 and the fourth agent 208, so the binary mask 402 the corresponding to these agents is striped. However, there is sensor data 110 in the observational dataset 404 regarding the first agent 202 and the third agent. Accordingly, the blocks at the third past time, t2, corresponding the first agent 202 and the third agent 206 are hashed. Accordingly, the spatial module 120 may generate the spatial missing pattern by applying the binary mask 402 to the observational dataset 404 to identify missing data.

At block 304 the method 300 includes the spatial module 120 extract spatial features from the spatial missing pattern for the number of past time steps. The spatial module 120 may include a Multi-Space Graph Neural Network (MS-GNN) 406 to support the capability of Graph Convolutional Layers (GCL). The spatial features are extracted from a plurality of feature spaces at the number of past time steps. The plurality of feature spaces includes a first feature space to learn spatial relationships and a second feature space that provides a mapping network to account for missing information in the observational dataset.

In one embodiment, each agent is represented as a node of the graph, the graph at time step t is defined as G^{t}=(V^{t}, Ε^{t}) where V^{t}={vᵢ^{t}|iε Ω} denotes a vertex set of agents and Ε^{t}={e_{i,j}^{t}|i ∈ Ω} denotes an edge set captured by and adjacent matrix At =fait j l i, j E The graph feature representation is defined as F^{t}={fᵢ^{t} ∈ [symbol] ^{D}|i ∈Ω} where fᵢ^{t} is the feature vector of node i at time step t, and D is the dimension of node feature vector. The inputs of the MS-GNN 406 include the observational dataset 404 and the corresponding binary mask 402 that indicates the missing value status of the observational dataset 404. In a training phase, the future trajectory of one or more agents may additionally be included as input to the MS-GNN 406. Take the first agent 202 represented by i at time step t as the example, the node feature is initialized by projecting inputs to high-dimensional feature vectors, which are defined as:

$${f}_{i}^{t} = \{ \begin{matrix}{φ}_{p} ( ( {x}_{i}^{t} ⊙ {m}_{i}^{t} ) ⊕ {m}_{i}^{t} ; {W}_{p} ) , & t ∈ [ {t}_{1} , {t}_{p} ] \\ {φ}_{f} ( {y}_{i}^{t} ; {W}_{f} ) , & t ∈ [ {t}_{p + 1} , {t}_{f} ]\end{matrix}$$

The different projection functions are φ(·) and φ_{f}(·) are weighted with Wₚ ∈ [symbol] ^{3×D} and W_{f} ∈ [symbol] ^{2×D} respectively. The weights may be implemented by the MS-GNN 406 using a multilayer perceptron (MLP). In the feature vectors, ⊙ is elementwise multiplication and ⊕ is a concatenation operation. In the training phase, yᵢ^{t} represents the future locations of the first agent 202 at time step t and acts as the ground truth for the MS-GNN 406.

The MS-GNN 406 may utilize the plurality of feature spaces may include a first feature space and second feature space to learn spatial relationships and a third feature space to provide a mapping network to account for missing information in the observational dataset 404. The feature spaces may correspond to three different graph convolutional layers (GCLs) to extract spatial features from different feature spaces at each time step. Each GCL is designed to extract primary features for intuitive purposes, and meanwhile emphasize the spatial correlations of missing patterns in the observational dataset 404. In one embodiment, the first feature space corresponds to a static topology GCL, the second feature space corresponds to a dynamic learnable GCL, and the third feature space corresponds to an edge conditioned GCL.

In the static topology GCL, the adjacency matrix only indicates the connectivity of node pairs, where A_{i,j}=1 if an edge directs from node i to j and 0 otherwise. One or more of the agents (i.e., nodes) are missing in the observed trajectory. Therefore, a different adjacency matrix Aₛₜ is defined not only to indicate the connectivity but also the visibility in static topology GCL. The identity matrix Iₛₜ is adjusted accordingly with a constraint for adding the self-loop. Constraints may be defined as A_{i,j}^{(t)}=A_{j,i}^{(t)}=1 if if node i and j are both visible at timestep t. Otherwise A_{i,j}^{(t)}=A_{j,i}^{(t)}=0, and I_{i,1}^{(t)}=1 if node i is visible at timestep t. Otherwise I_{i,1}^{(t)}=0. The propagation rule of graph feature Fₛₜ^{(l)} of the l-th static topology layer is defined as:

Fₛₜ^{(l+1)}=σ(\hat{A}ₛₜFₛₜ^{(l)}Wₛₜ^{(l)})

where normalized adjacency matrix Aₛₜ=D^{-1/2}(Âₛₜ+Iₛₜ)\tilde{D}^{-1/2}, where \tilde{D}is the diagonal degree of Aₛₜ+Iₛₜ, Wₛₜ^{(l)} ∈ [symbol] ^{D}^{^{(l)}}^{×}D^{(l+1)} are learnable parameters of the l-th static topology layer, and σ(·) denotes an activation function such as ReLU. This static topology GCL may model the connectivity and visibility features of agents in a fixed way.

In contrast to the Aₛₜ in the static topology GCL with fixed values (0 or 1), an unconstrained A_{di} to dynamically learn the strength of relations between nodes, and to improve the flexibility of the dynamic learnable GCL. A_{di} is initialized with random values and learns to strengthen, weaken, add, or remove edges during training. The propagation rule of graph feature F_{dl}^{(l)} is defined as:

F_{dl}^{(l+1)}=σ(A_{dl}F_{dl}^{(l)}W_{dl}^{(l)})

where W_{dl}^{(l)} ∈ [symbol] ^{D}^{^{(l)}}^{×D}^{^{(l+1)}} are learnable parameters of the l-th dynamic learnable layer. Since all the elements in A_{dl} are learnable with no constraint, the Adl will be asymmetric that allows each edge to select the best suitable relation strength to update its corresponding node features. Intuitively, compared to the static topology GCL, the relations among agents (nodes) are better captured by this GCL.

The static topology GCL and the dynamic learnable GCL focus on learning spatial relations among nodes and the different strengths of such relations by two different definitions of the adjacency matrix. The edge conditioned GCL assigns a label to each edge based on its category and integrate such category information in graph propagation. There are three different types of edges conditioned on the visibility of the corresponding node pair. The three categories are encoded into one-hot vectors v_{i,j} ∈ [symbol] ³, and then define a mapping network φ(·) to output the edge-specific weight matrix Θ_{i,j} ∈ [symbol] ^{D}^{_{G}}^{×D} for updating the node features. The updating rule in edge conditioned GCL is defined as follows:

$${f}_{ec , i} = \frac{1}{\vert 𝒱 ( i ) \vert} {\sum }_{j ∈ 𝒱 ( i )} {φ}_{ec} ( {ϑ}_{i , j} ; {W}_{ec} ) {f}_{j} + {b}_{ec} = \frac{1}{\vert 𝒱 ( i ) \vert} {\sum }_{j ∈ 𝒱 ( i )} {Θ}_{i , j} {f}_{j} + {b}_{ec}$$

where f_{ec,i} is the feature vector of node i in F_{ec}, W_{ec} are learnable parameters of the l-th edge conditioned layer, b_{ec} is a learnable bias, and V(i) denotes the neighborhood of node i. Then φ_{ec}(·) is implemented by a Conv2D block with two Conv2D layers and one average pooling layer. In this manner, the spatial features, Fₛₜ, F_{dl}, and F_{ec}, are extracted for the static topology GCL, the dynamic learnable GCL, and the edge conditioned GCL, respectively. The spatial features are integrated in to the final graph representation F_{G} ∈ [symbol] ^{N×D}^{_{G}} as follows:

F_{G}=αFₛₜ+βF_{dl}+γF_{ec}

where α, β, and γ are three learnable parameters for feature fusion with the same size [symbol] ^{D}^{_{G}}. Thus, continuing the example from above, the spatial features are combined into a final spatial feature.

At block 306 the method 300 includes the spatial module 120 encoding the one or more spatial features of the observational dataset 404 into imputation latent variables in a latent space based on the spatial missing pattern. The spatial module 120 may include a graph-based conditional variational recurrent neural network (GC-VRNN) 408 is a variational autoencoder conditioned on the hidden states of the RNN. The GC-VRNN 408 may be trained my maximizing the evidence lower bound (ELBO) as follows:

$${𝔼}_{{q}_{ϕ} ( {z}^{\leq T} \vert {x}^{\leq T} )} [ {\sum }_{t = 1}^{T} log {p}_{θ} ( {x}^{t} \vert {z}^{\leq t} , {x}^{< t} ) - KL ( {q}_{ϕ} ( {z}^{t} \vert {x}^{\leq t} , {z}^{< t} ) ‖ {p}_{θ} ( {z}^{t} \vert {x}^{< t} , {z}^{< t} ) ) ]$$

At each time step, the prior on the latent variables z^{t} follows the distribution:

$${z}^{t} \sim 𝒩 ( {μ}^{pri , t} , {σ}^{pri , {t}^{2}} )$$

where μ^{pri,t} and σ^{pri,t}^{²} denote distribution parameters that conditioned on

the hidden states h^{t-1} of an RNN as follows:

$$[ {μ}^{pri , t} , {σ}^{pri , {t}^{2}} ] = {φ}^{pri} ( {h}^{t - 1} ; {W}^{pri} )$$

where φ^{pri}(·) is a mapping function that maps hidden states to a prior distribution with weights W^{pri}. At time step t, a decoder 416 decode imputed trajectory or future prediction from latent variables. Turning to FIG. 4, the network architecture is shown directed to past times 424 for generating imputation trajectories 418 and future times 426 for predicting future trajectories 420. While the imputation trajectories 418 and the future trajectories 420 may be determined simultaneously. FIG. 4 is split to show the components for clarity. Reference numbers with prime accents are used to indicate outputs for the future times 426 that correspond to outputs for the past times 424.

The location (2D coordinates) of the agents 202-208 may follow a bivariate Gaussian distribution as x^{t}˜N(μ^{t}σ^{t}, ρ^{t}) where μ^{t} is the mean, a σ^{t} is the standard deviation, and ρ^{t} is the correlation coefficient.

For imputation, the generating distribution may be conditioned on z^{t} and the previous hidden states h^{t-1} such that:

$$[ {\hat{μ}}^{t} , {\hat{σ}}^{t} , {\hat{ρ}}^{t} ] = {φ}_{p}^{dec} ( {φ}_{p}^{z} ( {z}^{t} ) ⊕ {h}^{t - 1} ; {W}_{p}^{dec} ) \qquad t ∈ [ {t}_{1} , {t}_{p} ]$$

Differently, apart from z^{t} and the previous hidden states h^{t-1}, the predicting distribution is also conditioned on the latent variables z^{t}414, for the past times 424, of the last observed time step such that:

$$[ {\hat{μ}}^{t} , {\hat{σ}}^{t} , {\hat{ρ}}^{t} ] = {φ}_{f}^{dec} ( {φ}_{f}^{z} ( {z}^{t} ⊕ {z}^{{t}_{p}} ) ⊕ {h}^{t - 1} ; {W}_{f}^{dec} ) \qquad t ∈ [ {t}_{p + 1} , {t}_{f} ]$$

where φ^{dec}(·) is a decoding function with weights W^{dec} and φ^{z}(·) is a feature extractor of z^{t} to the latent variables z^{t}^{ₚ} 414 and then extract joint features. Intuitively, the feature information that is encoded by the imputation stream is also considered when decoding the predicting distribution into the latent variables z^{τ}^{_{f}} 414′.

At block 308 the method 300 includes generating a temporal missing pattern by modeling the temporal dependency from the past time to the first time based on the latent space using a temporal decay module 410. In order to extract temporal features of missing patterns in observations, a temporal lag δᵢ^{t} is used that indicates the relative distance between the last observable time step and the current time step t of agent i. The temporal decay module 410 calculates the temporal lag as follows:

$${δ}_{i}^{t} = \{ \begin{matrix}t - ( t - 1 ) + {δ}_{i}^{t - 1} & if t > 1 and {m}_{i}^{t} = 0 \\ t - ( t - 1 ) & if t > 1 and {m}_{i}^{t} = 0 \\ 0 & if t = 1\end{matrix}$$

The temporal decay module 410 Concatenate temporal lags δᵢ^{t} of all the agents at time step t, the temporal lag vector δ^{t} is obtained. Then, the temporal decay vector Δt is calculated as follows:

$${Δ}^{t} = 1 / exp ( max ( 0 , {W}_{δ} {δ}^{t} + {b}_{δ} ) )$$

where W_{δ} and b_{δ} are learnable parameters and bias. In sequential modeling, the influence of the input variables fade away over time if the variable has been missing for a while. Since the temporal lag δ^{t} represents the distance from the last observation to the current time step, the temporal lag and temporal decay are negatively correlated. Thus, a negative exponential function keeps temporal decay monotonically decreasing in a reasonable range between 0 and 1. The temporal decay vector may only be calculated and applied for the past incomplete trajectory. Accordingly, the temporal dependency is based on a temporal lag defined as an amount of time between the past time and the first time.

The temporal module 122 may recurrently update the observational dataset and the imputation latent variables. For example, if missing information cannot be represented by decayed values, the temporal module 122 may element-wise multiply hidden states and temporal decay vectors during the recurrence updating process as follows:

$${h}^{t - {1}^{′}} = {Δ}^{t} ⊙ {h}^{t - 1}$$

In this manner, the temporal decay module 410 generates the temporal missing pattern by modeling the temporal dependency from the past time to the first time based on the latent space. Accordingly, the recurrent update is based on hidden states.

At block 310 the method 300 includes the imputation module 124 determining imputation trajectories 418 based on the imputation latent variables 414 and the temporal missing pattern.

$${h}^{t} = RNN ( ( {F}_{𝒢}^{t} ⊕ {φ}_{p}^{z} ( {z}^{t} ) ) , {h}^{t - {1}^{′}} ) \qquad t ∈ [ {t}_{1} , {t}_{p} ]$$

At block 312 the method 300 includes the predictive module 126 predicting future trajectories 420 for the number of agents 202-208 for a number of future timesteps from second time, after the first time, to a future time; wherein the future trajectories and the imputation trajectories are determined simultaneously.

$${h}^{t} = RNN ( ( {F}_{𝒢}^{t} ⊕ {φ}_{f}^{z} ( {z}^{t} ⊕ {z}^{{t}_{p}} ) ) , {h}^{t - 1} ) \qquad t ∈ [ {t}_{p + 1} , {t}_{f} ]$$

When updating the hidden states in the prediction stream, the predictive module 126 concatenates latent variable z^{t} to z^{t}^{ₚ}.

The imputation trajectories 418 and the future trajectories 420 are determined simultaneously. More formally, that is learn a model f(·) with parameter W* that outputs \hat{X}_{Ω}^{≤t}^{ₚ} and Ŷ_{Ω}^{t}^{ₚ₊₁}^{≤t≤t}^{_{f}} where \hat{X}_{Ω}^{≤t}^{ₚ} refers to the imputed trajectory observations and Ŷ_{Ω}^{t}^{ₚ₊₁}^{≤t≤t}^{_{f}} refers to the predicted trajectory.

At each time step, the approximate posterior distribution of latent variables follows the distribution:

$$\begin{matrix}{z}^{t} \vert {x}^{t} \sim 𝒩 ( {μ}^{enc , t} , {σ}^{enc , {t}^{2}} ) & t ∈ [ {t}_{1} , {t}_{p} ] \\ {z}^{t} \vert {y}^{t} \sim 𝒩 ( {μ}^{enc , t} , {σ}^{enc , {t}^{2}} ) & t ∈ [ {t}_{p + 1} , {t}_{f} ]\end{matrix}$$

The posterior distribution is conditioned on graph representation and hidden

states of RNN as follows:

$$[ {μ}^{enc , t} , {σ}^{enc , {t}^{2}} ] = {φ}^{enc} ( ( {F}_{𝒢}^{t} ⊕ {h}^{t - 1} ) ; {W}^{enc} )$$

In some embodiments a loss function may be formed with two parts: L imp for imputation and Lₚᵣₑ for prediction, which are defined as follows:

$${ℒ}_{imp} = - {\sum }_{t = {t}_{1}}^{{t}_{p}} log ℙ ( {x}^{t} \vert {\hat{μ}}^{t} , {\hat{σ}}^{t} , {\hat{ρ}}^{t} ) + {λ}_{1} KL ( 𝒩 ( {μ}^{enc , t} , {σ}^{enc , {t}^{2}} ) ‖ 𝒩 ( {μ}^{pri , t} , {σ}^{pri , {t}^{2}} ) )$$

$${ℒ}_{pre} = - {\sum }_{t = {t}_{p + 1}}^{{t}_{f}} log ℙ ( {y}^{t} \vert {\hat{μ}}^{t} , {\hat{σ}}^{t} , {\hat{ρ}}^{t} ) + {λ}_{2} KL ( 𝒩 ( {μ}^{enc , t} , {σ}^{enc , {t}^{2}} ) ‖ 𝒩 ( {μ}^{pri , t} , {σ}^{pri , {t}^{2}} ) )$$

The total loss is given as:

L=Lᵢₘₚ+λ₃Lₚᵣₑ

where {λ1, λ2, λ3} are weighting factors. The weighting factors may be set as 1. The loss may be calculated over all agents in each trajectory. Thus, the model is trained end-to-end for the joint problem of imputation and prediction. One or more of the agents 202-208 may generate a path plan for navigating the environment, such as the roadway 200, based on the imputation and/or prediction.

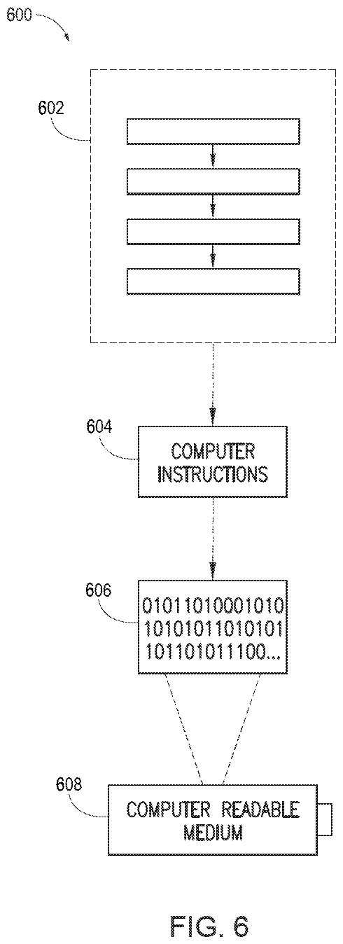

Still another aspect involves a computer-readable medium including processor-executable instructions configured to implement one aspect of the techniques presented herein. An aspect of a computer-readable medium or a computer-readable device devised in these ways is illustrated in FIG. 6, wherein an implementation 600 includes a computer-readable medium 608, such as a CD-ft DVD-R, flash drive, a platter of a hard disk drive, etc., on which is encoded computer-readable data 606. This encoded computer-readable data 606, such as binary data including a plurality of zero's and one's as shown in 606, in turn includes a set of processor-executable computer instructions 604 configured to operate according to one or more of the principles set forth herein.

In this implementation 600, the processor-executable computer instructions 604 may be configured to perform a method 602, such as the method 300 of FIG. 3. In another aspect, the processor-executable computer instructions 604 may be configured to implement a system, such as the operating environment 100 of FIG. 1. Many such computer-readable media may be devised by those of ordinary skill in the art that are configured to operate in accordance with the techniques presented herein.

As used in this application, the terms “component”, “module,” “system”, “interface”, and the like are generally intended to refer to a computer-related entity, either hardware, a combination of hardware and software, software, or software in execution. For example, a component may be, but is not limited to being, a process running on a processor, a processing unit, an object, an executable, a thread of execution, a program, or a computer. By way of illustration, both an application running on a controller and the controller may be a component. One or more components residing within a process or thread of execution and a component may be localized on one computer or distributed between two or more computers.

Further, the claimed subject matter is implemented as a method, apparatus, or article of manufacture using standard programming or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, many modifications may be made to this configuration without departing from the scope or spirit of the claimed subject matter.

Although the subject matter has been described in language specific to structural features or methodological acts, it is to be understood that the subject matter of the appended claims is not necessarily limited to the specific features or acts described above. Rather, the specific features and acts described above are disclosed as example aspects. Various operations of aspects are provided herein. The order in which one or more or all of the operations are described should not be construed as to imply that these operations are necessarily order dependent. Alternative ordering will be appreciated based on this description. Further, not all operations may necessarily be present in each aspect provided herein.

As used in this application, “or” is intended to mean an inclusive “or” rather than an exclusive “or”. Further, an inclusive “or” may include any combination thereof (e.g., A, B, or any combination thereof). In addition, “a” and “an” as used in this application are generally construed to mean “one or more” unless specified otherwise or clear from context to be directed to a singular form. Additionally, at least one of A and B and/or the like generally means A or B or both A and B. Further, to the extent that “includes”, “having”, “has”, “with”, or variants thereof are used in either the detailed description or the claims, such terms are intended to be inclusive in a manner similar to the term “comprising”.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also that various presently unforeseen or unanticipated alternatives, modifications, variations or improvements therein may be subsequently made by those skilled in the art which are also intended to be encompassed by the following claims.

1. A system for trajectory imputation and prediction, comprising:
a memory storing instructions that when executed by a processor cause the processor to:
generate a spatial missing pattern in an imputation stream by applying a binary mask to an observational dataset representing past actions for a number of agents over a number of past timesteps from a past time to a first time;
extract one or more spatial features from the spatial missing pattern for the number of past time steps;
encode the one or more spatial features of the observational dataset into imputation latent variables in a latent space based on the spatial missing pattern;
generate a temporal missing pattern by modeling temporal dependency as temporal decay from the past time to the first time based on the latent space;
determine imputation trajectories based on the imputation latent variables and the temporal missing pattern; and
predict future trajectories for the number of agents for a number of future timesteps from second time, after the first time, to a future time based temporal missing pattern.

2. The system of claim 1, wherein the one or more spatial features are extracted from a plurality of feature spaces at the number of past time steps.

3. The system of claim 2, wherein the plurality of feature spaces include a first feature space to learn spatial relationships and a second feature space that provides a mapping network to account for missing information in the observational dataset.

4. The system of claim 1, wherein the temporal dependency is based on a temporal lag defined as an amount of time between the past time and the first time, wherein the temporal lag and the temporal decay are negatively correlated.

5. The system of claim 1, wherein the instructions further cause the processor to recurrently update the observational dataset and the imputation latent variables.

6. The system of claim 5, wherein the recurrent update is further based on hidden states and the temporal decay includes a number of temporal decay vectors, and wherein the hidden states are element-wise multiplied by the temporal decay vectors.

7. The system of claim 1, wherein the imputation trajectories and the future trajectories are determined simultaneously.

8. A computer-implemented method for trajectory imputation and prediction, comprising:
generating a spatial missing pattern in an imputation stream by applying a binary mask to an observational dataset representing past actions for a number of agents over a number of past timesteps from a past time to a first time;
extracting one or more spatial features from the spatial missing pattern for the number of past time steps;
encoding the one or more spatial features of the observational dataset into imputation latent variables in a latent space based on the spatial missing pattern;
generating a temporal missing pattern by modeling temporal dependency as temporal decay from the past time to the first time based on the latent space;
determining imputation trajectories based on the imputation latent variables and the temporal missing pattern; and
predicting future trajectories for the number of agents for a number of future timesteps from second time, after the first time, to a future time based temporal missing pattern.

9. The computer-implemented method of claim 8, wherein the one or more spatial features are extracted from a plurality of feature spaces at the number of past time steps.

10. The computer-implemented method of claim 9, wherein the plurality of feature spaces include a first feature space to learn spatial relationships and a second feature space that provides a mapping network to account for missing information in the observational dataset.

11. The computer-implemented method of claim 8, wherein the temporal dependency is based on a temporal lag defined as an amount of time between the past time and the first time, wherein the temporal lag and the temporal decay are negatively correlated.

12. The computer-implemented method of claim 8, further comprising:
recurrently updating the observational dataset and the imputation latent variables.

13. The computer-implemented method of claim 12, wherein the recurrent update is further based on hidden states and the temporal decay includes a number of temporal decay vectors, and wherein the hidden states are element-wise multiplied by the temporal decay vectors.

14. The computer-implemented method of claim 8, wherein the imputation trajectories and the future trajectories are determined simultaneously.

15. A non-transitory computer readable storage medium storing instructions that when executed by a computer, which includes a processor perform a method, the method comprising:
generating a spatial missing pattern in an imputation stream by applying a binary mask to an observational dataset representing past actions for a number of agents over a number of past timesteps from a past time to a first time;
extracting one or more spatial features from the spatial missing pattern for the number of past time steps;
encoding the one or more spatial features of the observational dataset into imputation latent variables in a latent space based on the spatial missing pattern;
generating a temporal missing pattern by modeling temporal dependency as temporal decay from the past time to the first time based on the latent space;
determining imputation trajectories based on the imputation latent variables and the temporal missing pattern; and
predicting future trajectories for the number of agents for a number of future timesteps from second time, after the first time, to a future time based on the temporal missing pattern.

16. The non-transitory computer readable storage medium of claim 15, wherein the one or more spatial features are extracted from a plurality of feature spaces at the number of past time steps.

17. The non-transitory computer readable storage medium of claim 16, wherein the plurality of feature spaces include a first feature space to learn spatial relationships and a second feature space that provides a mapping network to account for missing information in the observational dataset.

18. The non-transitory computer readable storage medium of claim 15, wherein the temporal dependency is based on a temporal lag defined as an amount of time between the past time and the first time, wherein the temporal lag and the temporal decay are negatively correlated.

19. The non-transitory computer readable storage medium of claim 15, further comprising:
recurrently updating the observational dataset and the imputation latent variables, wherein the recurrent update is further based on hidden states and the temporal decay includes a number of temporal decay vectors, and wherein the hidden states are element-wise multiplied by the temporal decay vectors.

20. The non-transitory computer readable storage medium of claim 15, wherein the imputation trajectories and the future trajectories are determined simultaneously.
